(19) United States
(12) Patent Application Publication
(10) Pub. No.: US 2022/0416021 A1
(43) Pub. Date: Dec. 29, 2022

(54) WIDE-GAP SEMICONDUCTOR SUBSTRATE, APPARATUS FOR MANUFACTURING WIDE-GAP SEMICONDUCTOR SUBSTRATE, AND METHOD FOR MANUFACTURING WIDE-GAP SEMICONDUCTOR SUBSTRATE

(71) Applicant: SPP TECHNOLOGIES CO., LTD., Tokyo (JP)

(72) Inventors: Takashi YAMAMOTO, Amagasaki-shi (JP); Naoya Ikemoto, Amagasaki-shi (JP)

(73) Assignee: SPP TECHNOLOGIES CO., LTD., Tokyo (JP)

(21) Appl. No.: 17/902,209

(22) Filed: Sep. 2, 2022

Related U.S. Application Data
(63) Continuation-in-part of application No. 16/629,085, filed on Jan. 7, 2020.

(30) Foreign Application Priority Data
Jan. 17, 2018 (JP) 2018-005923

(51) Int. Cl. H01L 29/06; H01L 29/16; H01L 21/02; H01J 37/32

(52) U.S. Cl. CPC H01L 29/0657; H01L 29/1608; H01L 21/02035; H01J 37/32366; H01J 37/32651; H01J 37/32972; H01J 2237/334; H01J 37/321

(57) ABSTRACT

A wide-gap semiconductor substrate enables formation of a device having low power loss while maintaining high mechanical strength. The wide-gap semiconductor substrate (70) is obtained by placing a wide-gap semiconductor substrate onto a platen (15) disposed in a processing chamber (11) and etching and thinning only a first substrate region (70a), where a device (50) is formed, of the wide-gap semiconductor substrate by means of plasma generated from an etching gas. In the wide-gap semiconductor substrate (70), a connecting portion as a peripheral edge of the first substrate region (70a) connecting to a second substrate region (70b) surrounding the first substrate region (70a) includes an arc portion having a predetermined radius of curvature.

### TECHNICAL FIELD

The present invention relates to a wide-gap semiconductor substrate for forming a device on a surface thereof, an apparatus for manufacturing a wide-gap semiconductor substrate, and a method for manufacturing a wide-gap semiconductor substrate.

### BACKGROUND

In recent years, electronic devices have been reduced in size, thickness, and weight, reduced in power loss (enhanced in efficiency), and enhanced in functionality (performance). Accordingly, a thin semiconductor device has been developed which is manufactured with a thinned silicon substrate. Particularly, a vertical power device has lower power loss when a silicon substrate (wafer) is thinner; therefore, it is preferred that such a device is manufactured with a silicon substrate having a minimum thickness with necessary voltage withstanding property. To this end, in manufacturing a thin power device, a silicon substrate is thinned to a desired thickness by grinding a back surface, i.e., a surface opposite to a surface on which functional layers are formed, of the silicon substrate. However, there are problems that the silicon substrate is cracked or chipped due to warpage occurring in thinning the silicon substrate and that the thinned silicon substrate is cracked when being conveyed. To solve these problems, for example, a technology is disclosed in Japanese Patent No. 6004100 in which a back surface of a silicon substrate is thinned by grinding only an inner area of the back surface of the silicon substrate with a peripheral area thereof left ungrinded. This technology enables reduction of cracking and warpage of the silicon substrate.

Simultaneously, power devices are further required to have low on-state resistance and high withstand voltage. To meet these requirements, manufacture using a silicon carbide substrate instead of using a conventionally used silicon substrate has attracted attention. Silicon carbide has smaller crystal lattice constant (stronger interatomic bonding) than silicon, and has a band gap (2.2 eV or more, hereinafter referred to as “wide gap”) greater than a band gap of silicon (1.12 eV). Further, a silicon carbide substrate has dielectric breakdown field strength (unit: V/cm) approximately 10 times as high as that of a silicon substrate. That is to say, in the case of using a silicon carbide substrate instead of a silicon substrate to manufacture an equivalent voltage withstanding product (device), a silicon carbide substrate having a thickness equal to only one tenth of that of the silicon substrate is used. For example, provided that a silicon carbide substrate has a withstand voltage of 100 V/μm, a silicon carbide substrate having a thickness of 15 μm can be used for a device having a withstanding voltage of 1200 V that is lower than 1500 V. On the other hand, in the case of using a silicon substrate to obtain an equivalent withstand voltage, the silicon substrate has to have a thickness of about 150 μm. Therefore, in the case where a silicon carbide substrate is used to manufacture a device having a required withstand voltage, it is preferred that the silicon carbide substrate has a thickness equal to one tenth of a thickness a silicon substrate is required to have to manufacture the device. Such a device is manufactured as follows: functional layers are formed on a surface of a silicon carbide substrate and then areas marked off by predetermined division lines are formed on the functional layers; subsequently, the silicon carbide substrate is thinned to a predetermined thickness by grinding a back surface of the silicon carbide substrate with a grinding device; and thereafter the silicon carbide substrate is divided into device chips by cutting the silicon carbide substrate along the predetermined division lines with a cutting device, a laser processing device, or the like. The divided device chips are each used for a power device.

### SUMMARY

For example, Japanese Patent No. 6004100 discloses a wafer thinning technology in which a wafer reinforced by a support substrate that is affixed to the wafer is entirely thinned with a grinding device. However, as described in Japanese Patent No. 6004100, using a grinding device has a problem that, if the wafer is to be thinned to an extremely small thickness (for example, 50 μm or less, which depends on the material of the wafer), the wafer is cracked or warped. Further, in the case where the wafer is a wide-gap semiconductor substrate made of silicon carbide or the like, the wafer has much higher hardness than a silicon substrate. Therefore, there is a problem that, when the back surface of the wafer is grinded with a grinding wheel including abrasives, the abrasives are worn out 4 to 5 times as much as the amount of grinding, which is very uneconomical. For example, abrasives are worn out by 0.1 μm when grinding a silicon substrate by 100 μm. On the other hand, abrasives are worn out by 400 to 500 μm when grinding a silicon carbide substrate by 100 μm; thus, abrasives are worn out 4000 to 5000 times as much as in the case of grinding a silicon substrate.

Further, Japanese Patent No. 6004100 proposes that, in the case of thinning a wafer made of silicon carbide (SiC), the wafer is thinned by CMP because a SiC wafer cannot be melted. However, polishing a SiC wafer by CMP is impractical because of its low polishing rate. Further, both grinding and CMP have difficulty in thinning a recess having a small rectangular area and difficulty in discharging shavings from a recess, and have a problem that it is necessary to remove distortion.

Further, power devices are required to have lower on-state resistance and higher withstand voltage; therefore, a wafer for such a power device is required to be further thinned.

The present disclosure relates to a wide-gap semiconductor substrate (hereinafter in this section, simply referred to as “semiconductor substrate”) for forming a device thereon, the semiconductor substrate having a first substrate region as an inner region having a recessed shape and a second substrate region as a region formed to surround an outer periphery of the first substrate region, wherein a connecting portion as a peripheral edge of the recessed shape of the first substrate region connecting to the second substrate region includes in its vertical cross section shape an arc portion having a predetermined radius of curvature, and the device is formed on the first substrate region.

Where a semiconductor substrate having a first substrate region (thin-plate part) as an inner region having a recessed shape and a second substrate region (thick-plate part) formed to surround the first substrate region is configured such that a connecting portion between the first substrate region and the second substrate region has a vertical cross section of a sharply changing shape, stress is likely to concentrate at the connecting portion; therefore, such a semiconductor substrate has the characteristic that it is easily broken at the connecting portion when an external force is applied thereto. The semiconductor substrate according to the present disclosure is configured such that the connecting portion between the first substrate region and the second substrate region includes in its vertical cross section shape the arc portion having a predetermined radius of curvature, so that the connecting portion between the first substrate region and the second substrate region has a vertical cross section of a shape which gradually or gently changes at the arc portion. Therefore, the semiconductor substrate according to the present disclosure is capable of alleviating the stress concentration at the connecting portion upon application of an external force, which reduces the risk of breakage at the connecting portion.

In terms of the alleviation of the stress concentration, the radius of curvature of the arc portion of the connecting portion is preferably not less than 0.1 μm, more preferably not less than 1 μm. Simultaneously, in terms of efficiency of device formation, the radius of curvature is preferably not more than 1000 μm, more preferably not more than 100 μm.

In the semiconductor substrate described above, it is preferred that a first thickness as a thickness of a region located on the inner side of the connecting portion of the first substrate region is not less than 10 μm and not more than 50 μm, a second thickness as a thickness of the second substrate region is not less than 100 μm and not more than 350 μm, and a radial width of the second substrate region is not less than 1 mm and not more than 10 mm. Such a semiconductor substrate is effectively prevented from being cracked or warped and enables a device formed on the thin-plate part thereof to have low on-state resistance. Therefore, it is possible to form a device having low power loss with mechanical strength of the semiconductor substrate maintained at high level.

Further, in the semiconductor substrate described above, it is preferred that the first substrate region is formed by dry etching. Because of the first substrate region being formed by dry etching, such a semiconductor substrate does not require its back surface to be grinded with abrasives that are expensive and easily worn out. Therefore, the cost for manufacturing such a semiconductor substrate is greatly reduced as compared with the case of manufacture using abrasives that need to be replaced each time they are worn out.

Further, in the semiconductor substrate described above, it is preferred that the semiconductor substrate is made of silicon carbide (4H—SiC, 6H—SiC, or 3C—SiC), gallium nitride (GaN), gallium oxide (GaO), or diamond (C).

Such a semiconductor substrate has a band gap (2.2 eV or more) greater than a band gap of silicon (1.12 eV). Therefore, this semiconductor substrate enables a device formed on the thin-plate part, i.e., the first substrate region, thereof to have lower on-state resistance, so that the device has lower power loss.

The semiconductor substrate described above is preferably manufactured by a manufacturing apparatus having a configuration as described below. This manufacturing apparatus is configured to thin a device formation region of a semiconductor substrate placed on a platen disposed in a processing chamber by etching using plasma generated from an etching gas to form a first substrate region as an inner region having a recessed shape and a second substrate region as an annular region surrounding an outer periphery of the first substrate region and is able to perform the etching such that a connecting portion as a peripheral edge of the recessed shape of the first substrate region connecting to the second substrate region includes in its vertical cross section shape an arc portion having a predetermined radius of curvature, the apparatus including an outer-periphery covering mechanism including a cover member covering, during the etching, the second substrate region of the semiconductor substrate placed on the platen to cause the device formation region not covered by the cover member to be etched and thinned.

This manufacturing apparatus includes the outer-periphery covering mechanism that covers the second substrate region of the semiconductor substrate placed on the platen with the cover member during etching of the semiconductor substrate so that the second substrate region of the semiconductor substrate is not etched. Therefore, the cover member functions as a mask, so that the second substrate region of the semiconductor substrate is not etched, while the device formation region of the semiconductor substrate is etched. Thus, with this manufacturing apparatus, it is easy to thin only an inner region, where a device is formed, of a semiconductor substrate. Further, thinning only the inner region enables the semiconductor substrate to be effectively prevented from being cracked or warped. Furthermore, the thus-manufactured semiconductor substrate enables a device formed on the thin-plate part thereof to have low on-state resistance.

Further, this manufacturing apparatus may have a configuration in which the outer-periphery covering mechanism further includes a support member provided in the processing chamber to support the cover member and the support member supports the cover member with a gap formed between the cover member and the semiconductor substrate. Further, it is preferred that the gap is set to be not less than 0.5 mm and not more than 3 mm.

Further, in the manufacturing apparatus described above, it is preferred that the outer-periphery covering mechanism further includes a support member provided in the processing chamber to support the cover member and the outer-periphery covering mechanism is configured such that the cover member is brought into contact with and raised by the second substrate region of the semiconductor substrate when the semiconductor substrate is lifted by the platen, thereby covering the second substrate region of the semiconductor substrate placed on the platen so that the second substrate region is not etched.

Further, in the manufacturing apparatus described above, it is preferred that the manufacturing apparatus further includes a depth monitor detecting a depth of etching of the semiconductor substrate and the depth monitor includes a depth sensor including a light source radiating a light toward an etched surface of the semiconductor substrate and the cover member, and a processing unit calculating the depth of etching based on reflected lights reflected by the etched surface and the cover member.

With such a manufacturing apparatus, it is possible to start etching without carrying out previous steps such as measuring in advance an etching amount and calculating an etching rate (i.e., setting conditions) so as to recognize an etching end point based on the etching rate and an etching time. Therefore, with this manufacturing apparatus, the time for manufacturing the semiconductor substrate is greatly reduced.

Further, in the manufacturing apparatus described above, it is preferred that the semiconductor substrate is made of silicon carbide (4H—SiC, 6H—SiC, or 3C—SiC), gallium nitride (GaN), gallium oxide (GaO), or diamond (C).

Such a semiconductor substrate has a band gap (2.2 eV or more) greater than a band gap of silicon (1.12 eV). Therefore, this semiconductor substrate enables a device formed on the thin-plate part thereof to have lower on-state resistance, so that the device has lower power loss.

The semiconductor substrate described above is preferably manufactured by a manufacturing method including steps as described below. This manufacturing method is configured to thin a device formation region of a semiconductor substrate placed on a platen disposed in a processing chamber by etching using plasma generated from an etching gas to form a first substrate region as an inner region having a recessed shape and a second substrate region as an annular region surrounding an outer periphery of the first substrate region and is able to perform the etching such that a connecting portion as a peripheral edge of the recessed shape of the first substrate region connecting to the second substrate region includes in its vertical cross section shape an arc portion having a predetermined radius of curvature, the method including:

placing the semiconductor substrate onto the platen disposed in the processing chamber and covering the second substrate region of the semiconductor substrate with a cover member;

supplying the etching gas into the processing chamber and generating the plasma from the etching gas; and

applying a bias potential to the platen to etch and thin the device formation region corresponding to the first substrate region of the semiconductor substrate.

In this manufacturing method, the second substrate region of the semiconductor substrate placed on the platen is covered with the cover member during etching of the semiconductor substrate so that the second substrate region is not etched; therefore, the second substrate region of the semiconductor substrate is not etched. Thus, with this manufacturing method, a semiconductor substrate can be manufactured which has a thin-plate part, i.e., the first substrate region, formed at an inner region thereof and has a thick-plate part, i.e., the second substrate region, formed around an outer periphery of the thin-plate part. Such a semiconductor substrate is effectively prevented from being cracked or warped. Further, a device manufactured by forming it on the thin-plate part of such a semiconductor substrate has low on-state resistance.

Note that, in this manufacturing method, it is preferred that a gap is formed between the semiconductor substrate and the cover member. In the case where the cover member is in contact with the semiconductor substrate when the semiconductor substrate is etched in a state where a bias potential is applied to the platen, depending on the material of the cover member, a bias potential is generated in the cover member. This causes a problem that the cover member is sputtered by ions in the plasma and the product of the sputtering adheres to the surface of the inner region, i.e., the surface of the thin-plat part, of the semiconductor substrate, which deteriorates surface accuracy of the surface of the thin-plat part. Forming a gap between the semiconductor substrate and the cover member enables prevention of generation of a bias potential in the cover member, which prevents the surface accuracy of the surface of the thin-plate part from being deteriorated due to the cover member being sputtered.

It is preferred that the gap between the semiconductor substrate and the cover member is not less than 0.5 mm and not more than 3 mm. In the case where the gap is smaller than 0.5 mm, generation of a bias potential in the cover member is not effectively prevented. In the case where the gap is equal to or greater than 3 mm, an etching species enters between the semiconductor substrate and the cover member and etches the region covered by the cover member (the second substrate region) of the semiconductor substrate, which results in deterioration of the shape of the semiconductor substrate obtained, such as an inner peripheral edge (inner shoulder) of the second substrate region (the thick-plate part) being etched.

Further, it is preferred that the cover member is made of quartz, aluminum oxide, or yttria or made of a material made by coating quartz, aluminum oxide, or yttria with a metal coating. Using aluminum oxide is disadvantageous in that sputtering as described above is likely to occur and such sputtering leads to deterioration of the surface accuracy of the surface of the thin-plate part, while it is advantageous in that the cover member is inexpensive to manufacture. Using yttria is disadvantageous in that the cover member is expensive to manufacture, while it is advantageous in that, even when sputtering as described above occurs, the product of the sputtering is likely to disappear and therefore the surface accuracy of the surface of the thin-plate part is less deteriorated. Further, using quartz is advantageous in that the cover member is less expensive to manufacture than in the case of using yttria and in that, even when sputtering as described above occurs, the product of the sputtering disappears and therefore the surface accuracy of the surface of the thin-plate part is hardly deteriorated. In the case of using quartz, although the cover member is etched by an etching species, loading is alleviated by the etching of the cover member, so that the thin-plate part is etched to have a uniform thickness.

In this manufacturing method, it is preferred that the etching is performed such that a region located on the inner side of the connecting portion of the first substrate region has a thickness (first thickness) of not less than 10 μm and not more than 50 μm. In such a manufacturing method, the device formation region of the semiconductor substrate is etched to have a thickness of not less than 10 μm and not more than 50 μm. Therefore, this manufacturing method enables a device formed on the thinned region to have lower on-state resistance, so that the device has lower power loss.

In this manufacturing method, it is preferred that, before the etching gas is supplied into the processing chamber for the etching, the semiconductor substrate is preheated by supplying an inert gas into the processing chamber and generating plasma from the inert gas and applying a bias potential to the platen. Further, it is preferred that the semiconductor substrate is preheated to 200° C. or more. Preheating the semiconductor substrate increases the effect of etching by reaction in the etching following the preheating, so that the arc portion is more easily formed at the connecting portion between the first substrate region and the second substrate region.

In this manufacturing method, it is preferred that the etching gas includes a fluorine-containing gas.

In this manufacturing method, it is preferred that the bias potential is applied to the platen by supplying an RF power of 50 W or more to the platen and a pressure inside the processing chamber is 30 Pa or less.

Because of the bias potential being applied to the platen by supplying an RF power of 50 W or more to the platen, such a manufacturing method etches even a semiconductor substrate with strong interatomic bonding rapidly. Further, because the pressure inside the processing chamber is 30 Pa or less, the plasma is stabilized and in-plane uniformity of the amount of etching is thereby enhanced.

In this manufacturing method, it is preferred that the semiconductor substrate is made of silicon carbide (4H—SiC, 6H—SiC, or 3C—SiC), gallium nitride (GaN), gallium oxide (GaO), or diamond (C).

In such a case, the semiconductor substrate has a band gap (2.2 eV or more) greater than a band gap of silicon (1.12 eV). Therefore, a device formed on the thin-plate part of the semiconductor substrate has lower on-state resistance, so that the device has lower power loss.

The wide-gap semiconductor substrate according to the present disclosure is configured such that the connecting portion between the first substrate region and the second substrate region includes the arc portion having a predetermined radius of curvature; therefore, the connecting portion between the first substrate region and the second substrate region has a vertical cross section of a shape which gradually or gently changes at the arc portion. This alleviates the stress concentration at the connecting portion upon application of an external force, which reduces the risk of breakage at the connecting portion.

Further, the wide-gap semiconductor substrate according to the present disclosure has a thin-plate part, i.e., the first substrate region, formed as an inner region where a device is formed, and has a thick-plate part, i.e., the second substrate region, formed around an outer periphery of the thin-plate part. With this wide-gap semiconductor substrate, it is possible to form a device having low power loss with mechanical strength of the wide-gap semiconductor substrate maintained at high level.

Further, the wide-gap semiconductor substrate manufacturing apparatus according to the present disclosure is configured such that the second substrate region of the wide-gap semiconductor substrate is covered so that the second substrate region is not etched; therefore, the second substrate region of the wide-gap semiconductor substrate is not etched. With this manufacturing apparatus, it is easy to thin only the inner region where a device is formed.

Furthermore, the wide-gap semiconductor substrate manufacturing method according to the present disclosure is configured such that the second substrate region of the wide-gap semiconductor substrate is covered during etching of the wide-gap semiconductor substrate so that the second substrate region is not etched. With this manufacturing method, it is easy to thin only the inner region where a device is formed.

The features, functions, and advantages that have been discussed can be achieved independently in various embodiments or may be combined in yet other embodiments further details of which can be seen with reference to the following description and drawings.

### BRIEF DESCRIPTION OF THE DRAWINGS

FIG. 1 shows (a) a vertical sectional view of a semiconductor substrate according to a first embodiment and (b) a plan view of the semiconductor substrate;

FIG. 2 is an enlarged view of the circled area A in FIG. 1 showing a connecting portion between a first substrate region and a second substrate region;

FIG. 3 is an enlarged view of the circled area A in FIG. 1 showing an alternative form of the connecting portion between the first substrate region and the second substrate region;

FIG. 4 is an enlarged view of the circled area A in FIG. 1 showing an alternative form of the connecting portion between the first substrate region and the second substrate region;

FIG. 5 is an enlarged view of the circled area A in FIG. 1 showing an alternative form of the connecting portion between the first substrate region and the second substrate region;

FIG. 6 is a sectional view of a schematic configuration of an etching apparatus (manufacturing apparatus) used for manufacturing the semiconductor substrate illustrated in FIG. 1;

FIG. 7 is an illustrative diagram showing steps for manufacturing the semiconductor substrate illustrated in FIG. 1;

FIG. 8 is an illustrative diagram showing steps for manufacturing the semiconductor substrate illustrated in FIG. 1;

FIG. 9 is an illustrative diagram showing etching conditions;

FIG. 10 is a vertical sectional view of a schematic configuration of an etching apparatus (manufacturing apparatus) according to a second embodiment;

FIG. 11 is a diagram illustrative of a manufacturing method and a manufacturing apparatus according to another embodiment;

FIG. 12 is a plan view of a wide-gap semiconductor substrate according to another embodiment; and

FIG. 13 is a plan view of a cover member used for manufacturing the wide-gap semiconductor substrate illustrated in FIG. 11.

It should be understood that the drawings are not necessarily drawn to scale and that the disclosed embodiments are sometimes illustrated schematically. It is to be further appreciated that the following detailed description is merely exemplary in nature and is not intended to limit the invention or the application and uses thereof. Hence, although the present disclosure is, for convenience of explanation, depicted and described as certain illustrative embodiments, it will be appreciated that it can be implemented in various other types of embodiments and in various other systems and environments.

### DETAILED DESCRIPTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

Hereinafter, embodiments of the present disclosure will be described with reference to the drawings.

### First Embodiment

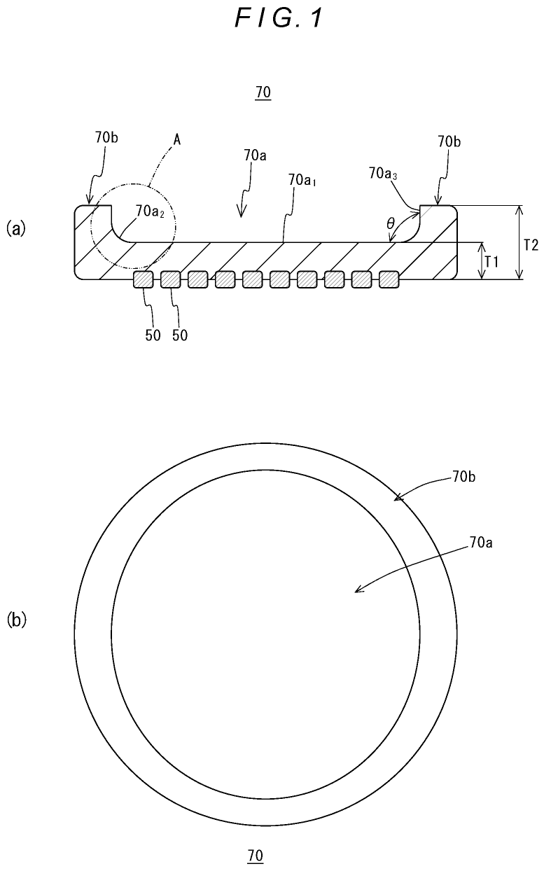

FIG. 1(a) is a vertical sectional view of a semiconductor substrate 70 according to a first embodiment. FIG. 1(b) is a plan view of the semiconductor substrate 70. The semiconductor substrate 70 is a wide-gap semiconductor substrate made of silicon carbide (4H—SiC) having high voltage withstanding properties. An electronic device manufactured with this semiconductor substrate 70 has low power loss, which is used as a high-performance and power-saving inverter, power module for household electrical appliance, or power semiconductor device for electric vehicle.

Further, silicon carbide has a higher Young's modulus than silicon and has the property of having high yield temperature even in a high-temperature environment. Therefore, silicon carbide is used as a MEMS (Micro-Electro Mechanical Systems) device having both electric circuit elements and fine mechanical elements, which is currently used in an acceleration sensor, a printer head, a pressure sensor, a DMD (Digital Micromirror Device), etc. and the market scale of which is increasingly expanded.

As shown in FIGS. 1(a) and 1(b), the semiconductor substrate 70 according to this embodiment has a first substrate region 70a as an inner region having a recessed shape and a second substrate region 70b as a region formed to surround the outer periphery of the first substrate region 70a. The first substrate region 70a has a circular shape in plan view and the bottom thereof has a thickness T1 (not less than 10 μm and not more than 50 μm). The second substrate region 70b has an annular shape having a thickness T2 (>T1). Note that the first substrate region 70a may have any area, which is determined in accordance with a mechanical strength the semiconductor substrate 70 is required to have.

As shown in FIG. 1(a), devices 50 each having a size of several mm square are formed on a surface opposite to the bottom surface of the first substrate region 70a (i.e., a back surface of the first substrate region 70a that is illustrated as the lower surface in FIG. 1(a)). The devices 50 include vertical power devices (an insulated gate bipolar transistor (IGBT), a MOS field effect transistor (MOSFET), a diode, etc.). Note that, although the devices 50 in this embodiment are formed on the back surface of the first substrate region 70a, the present disclosure is not limited thereto. The devices 50 may be formed on the bottom surface of the first substrate region 70a (i.e., the upper surface of the first substrate region 70a in FIG. 1(a)).

The second substrate region 70b as the outer region serves to maintain the mechanical strength of the semiconductor substrate 70 so as to prevent the semiconductor substrate 70 from being cracked or warped while it is conveyed or subjected to heat treatment. To this end, it is preferred that the thickness (second thickness) T2 of the second substrate region 70b is not less than 100 μm and not more than 350 μm. Setting the thickness T2 in this range enables the semiconductor substrate 70 to be effectively prevented from being cracked or warped. Simultaneously, it is preferred that the thickness (first thickness) T1 of the bottom of the first substrate region 70a is not less than 10 μm and not more than 50 m. Setting the thickness T1 in this range enables the devices 50 formed on the first substrate region 70a to have low on-state resistance, while the mechanical strength of the semiconductor substrate 70 is maintained at high level. Therefore, it is possible to manufacture a device having lower power loss with the mechanical strength of the semiconductor substrate 70 maintained at high level.

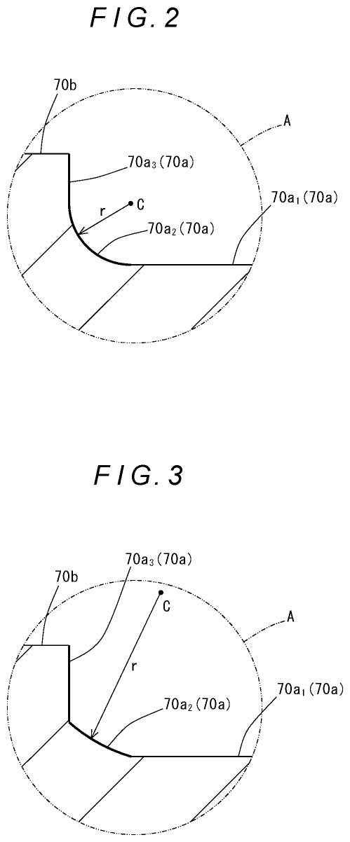

Further, as illustrated in FIG. 2, the semiconductor substrate 70 according to this embodiment is configured such that a connecting portion as a peripheral edge of the first substrate region 70a connecting to the second substrate region 70b (the portion indicated by the bold solid line in FIG. 2) includes, in its vertical cross section shape, a linear portion (inner peripheral surface) 70a₃ connecting to the second substrate region 70b and an arc portion 70a₂ having a predetermined radius of curvature r and connecting the linear portion 70a₃ and a linear portion (planar surface) 70a₁ located on the inner side of the connecting portion.

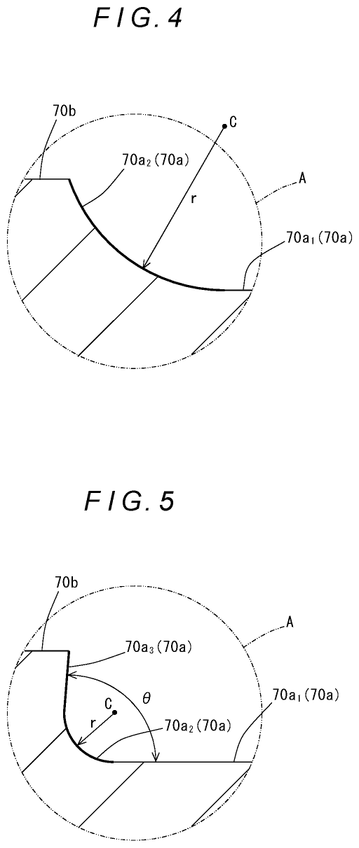

By way of example, the connecting portion may be formed to have a vertical cross section of a shape in which the arc portion 70a₂ is in the shape of a quadrant of a circle tangent to both the linear portion 70a₁ and the linear portion 70a₃ as illustrated in FIG. 2; however, the present disclosure is not limited thereto. For example, the connecting portion may be formed such that the arc portion 70a₂ is tangent to neither the linear portion 70a₁ nor the linear portion 70a₃ as illustrated in FIG. 3, in other words, both the linear portion 70a₁ and the liner portion 70a₃ are not tangent to the arc portion 70a₂. Alternatively, although not illustrated in the drawings, the connecting portion may be formed such that the arc portion 70a₂ is tangent to one of the linear portion 70a₁ and linear portion 70a₃ but is not tangent to the other of them. Alternatively, the connecting portion may be formed by the arc portion 70a₂ alone as illustrated in FIG. 4. In FIG. 3, the arc portion 70a₂ and linear portion 70a₃ that form the connecting portion are indicated by a bold solid line. In FIG. 4, the arc portion 70a₂ that forms the connecting portion is indicated by a bold solid line.

If the semiconductor substrate 70 having the first substrate region 70a as the inner region having a recessed shape and the second substrate region 70b formed to surround the first substrate region 70a is configured such that the connecting portion between the first substrate region 70a and the second substrate region 70b has a vertical cross section of a sharply changing shape, stress is likely to concentrate at the connecting portion; therefore, such a semiconductor substrate 70 has the characteristic that it is easily broken at the connecting portion when an external force is applied thereto. The semiconductor substrate 70 according to this embodiment is configured such that the connecting portion between the first substrate region 70a and the second substrate region 70b includes in its vertical cross section shape the arc portion 70a₂ having a predetermined radius of curvature r, so that the connecting portion between the first substrate region 70a and the second substrate region 70b has a vertical cross section of a shape which gradually or gently changes at the arc portion 70a₂. Therefore, the semiconductor substrate 70 according to this embodiment is capable of alleviating the stress concentration at the connecting portion upon application of an external force, which reduces the risk of breakage at the connecting portion.

Note that, in terms of the alleviation of the stress concentration, the radius of curvature r of the arc portion 70a₂ of the connecting portion is preferably not less than 0.1 μm, more preferably not less than 1 μm. Simultaneously, in terms of efficiency of formation of the devices 50, which is described later, the radius of curvature r is preferably not more than 1000 μm, more preferably not more than 100 μm.

Further, in the case where the connecting portion of the first substrate region 70a includes the linear portion 70a₃, it is preferred that the angle θ between the linear portion 70a₃ and the linear portion 70a₁ is not less than 800 and not more than 100°. If the angle θ is more than 1000 in the semiconductor substrate 70 configured such that the second substrate region 70b has a constant radial width, there is an advantage that the semiconductor substrate 70 has an increased strength, but there is a disadvantage that the number of devices 50 allowed to be formed on the first substrate region 70a is reduced, that is to say, the efficiency of formation of the devices 50 is reduced. On the other hand, if the angle θ is less than 80°, there is an advantage that the number of devices 50 allowed to be formed on the first substrate region 70a is increased, that is to say, the efficiency of formation of the devices 50 is increased, but there is a disadvantage that the semiconductor substrate 70 has a decreased strength.

Note that the first substrate region 70a in this embodiment has by way of example a circular planer shape; however, the present disclosure is not limited thereto. For example, the planar shape of the first substrate region 70a may be a rectangular shape, a rounded quadrangular shape (quadrangular shape with rounded corners), or a polygonal shape. The first substrate region 70a may have any planar shape which is appropriate to the shapes of devices to be formed thereon. Such a configuration also provides the same effects as the example described here. Furthermore, this embodiment describes an example configuration in which a single recess that corresponds to the first substrate region 70a is formed; however, a configuration is possible in which two or more recesses are formed.

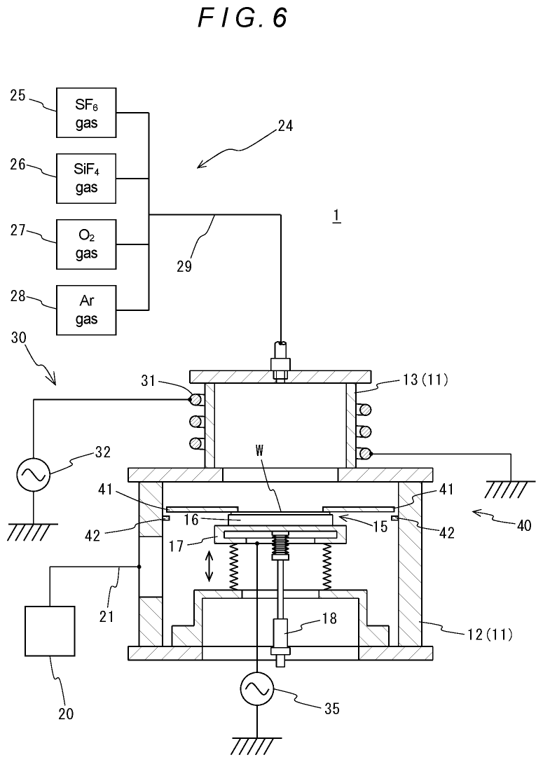

Next, an etching apparatus 1, which is a manufacturing apparatus for manufacturing the semiconductor substrate 70 according to this embodiment, is described with reference to FIG. 6. FIG. 6 is a sectional view of a schematic configuration of the etching apparatus 1 used for manufacturing the semiconductor substrate 70 illustrated in FIG. 1.

As shown in FIG. 6, the etching apparatus 1 includes a processing chamber 11 having a closed space, a platen 15 which is disposed in the processing chamber 11 in such a manner that it is able to be lifted and lowered and on which a wafer W to be etched is to be placed, a lifting cylinder (lifting device) 18 lifting and lowering the platen 15, an exhaust device 20 reducing the pressure inside the processing chamber 11, a gas supply device (processing gas supply unit) 24 supplying a processing gas into the processing chamber 11, a plasma generating device 30 generating plasma from the processing gas supplied into the processing chamber 11, an RF power supply (platen power supply unit) 35 supplying RF power to the platen 15, and an outer-periphery covering mechanism 40 covering a peripheral edge portion (non-etched portion) of the wafer W. This etching apparatus 1 etches a wafer W placed on the platen 15 disposed in the processing chamber 11 by means of plasma generated from an etching gas so that only a device formation region of the wafer W, where a device is to be formed, is thinned. Note that the outer-periphery covering mechanism 40 functions to cover only the peripheral edge portion of the wafer W placed on the platen 15 during etching of the wafer W so that only the peripheral edge portion is not etched.

The processing chamber 11 is composed of a lower chamber 12 and an upper chamber 13, interior spaces of which communicate with each other. The upper chamber 13 is formed to be smaller than the lower chamber 12. The platen 15 is composed of an upper member 16 on which a wafer W is to be placed, and a lower member 17 to which the lifting cylinder 18 is connected. The platen 15 is disposed in the lower chamber 12.

The outer-periphery covering mechanism 40 includes a cover member 41 and a support member 42. The cover member 41 is disposed in the lower chamber 12 and has an annular (doughnut) shape in plan view so as to cover only a peripheral edge portion of the wafer W placed on the platen 15 when the platen 15 is lifted, thereby functioning as a mask in etching. The support member 42 is formed annularly on an inner wall of the lower chamber 12 to support the cover member 41. The support member 42 is configured to support an outer peripheral edge of the cover member 41. Note that this embodiment is configured such that the cover member 42 supports the cover member 41 at the entire outer peripheral edge of the cover member 41; however, the present disclosure is not limited thereto. For example, a configuration is possible in which inwardly protruding members are provided at several (for example, four) positions on the inner wall of the lower chamber 12 and the cover member 41 is supported by the inwardly protruding members. Note further that this embodiment is configured such that the platen 15 on which a wafer W is to be placed is lifted and lowered; however, the present disclosure is not limited thereto. A configuration is possible in which the platen 15 is fixed and the cover member 41 is lifted and lowered instead. Note further that the cover member 41 in this embodiment is formed in a shape such that the first substrate region 70a is etched to have a circular planar shape; however, the present disclosure is not limited thereto. For example, the cover member 41 may be formed in a shape such that the first substrate region 70a is etched to have a non-circular planar shape, such as a rectangular planar shape, a rounded quadrangular planar shape (quadrangular planar shape with rounded corners), or a polygonal planar shape. Thus, the first substrate region 70a can be formed into any shape by changing the shape of the cover member 41. Further, the problem of shavings produced in grinding or the like is avoided.

The cover member 41 in this embodiment is made of a ceramic material, such as alumina (aluminum oxide), in view of etching selectivity of the cover member 41 and the wafer W. However, the present disclosure is not limited thereto. The cover member 41 may be made of yttrium or a material having a low dielectric constant, such as quartz. Alternatively, the cover member 41 may be made of a material made by coating alumna, quartz, or yttrium with a metal coating such as a nickel coating.

Using aluminum oxide is disadvantageous in that sputtering is likely to occur in an etching process as described later and such sputtering leads to deterioration of surface accuracy of the surface Pa of the first substrate region 70a, while it is advantageous in that the cover member 41 is inexpensive to manufacture. Using yttria is disadvantageous in that the cover member 41 is expensive to manufacture, while it is advantageous in that, even when sputtering as described above occurs, the product of the sputtering is likely to disappear and therefore the surface accuracy of the surface Pa of the first substrate region 70a is less deteriorated. Using quartz is advantageous in that the cover member 41 is less expensive to manufacture than in the case of using yttria and in that, even when sputtering as described above occurs, the product of the sputtering disappears and therefore the surface accuracy of the surface Pa of the first substrate region 70a is hardly deteriorated. In the case of using quartz, although the cover member 41 is etched by an etching species, loading is alleviated by the etching of the cover member 41, so that the first substrate region 70a is etched to have a uniform thickness.

Next, operation of the outer-periphery covering mechanism 40 is described.

First, when the platen 15 has been lowered by the lifting cylinder 18, the cover member 41 is supported by the support member 42 at the outer peripheral edge thereof. In this state, a wafer W, which is not yet etched, is placed onto the platen 15. Subsequently, the platen 15 and the wafer W placed thereon are lifted by the lifting cylinder 18 for an etching process, whereby the cover member 41 is brought into contact with an upper surface of a peripheral edge portion of the wafer W and then the cover member 41 is raised along with the lifted wafer W. In this process, only the peripheral edge portion of the wafer W placed on the platen 15 is covered by the cover member 41. The cover member 41 functions as a mask in the etching process.

After the etching process is finished, the platen 15 is lowered by the lifting cylinder 18, whereby the cover member 41 is supported by the support member 42. In this state, the etched wafer W (semiconductor substrate 70) is unloaded from the etching apparatus 1, and a wafer W to be etched next is loaded into the etching apparatus 1 and placed onto the platen 15.

Using this outer-periphery covering mechanism 40 allows an outer peripheral area of a width of about 3 mm of the upper surface of the wafer W to remain unetched, so that only an inner area of the upper surface of the wafer W is etched and thereby the inner region of the wafer W is thinned. This configuration enables reduction of cracking and warpage of the etched wafer W (semiconductor substrate 70).

Note that this embodiment is configured such that a wafer W is placed onto the upper member 16; however, the present disclosure is not limited thereto. For example, a configuration is possible in which an electrostatic chuck having an electrode plate clamped between a pair of insulating layers is used and an appropriate voltage is applied to the electrode plate so that a wafer W is attracted to and held on the electrostatic chuck. Such a configuration also provides the same effects as this embodiment.

The exhaust device 20 includes an exhaust pipe 21 connected to a side surface of the lower chamber 12. The exhaust device 20 exhausts gas from the processing chamber 11 through the exhaust pipe 21 to set the pressure inside the processing chamber 11 to a predetermined pressure.

The gas supply device 24 includes a gas supply unit 25 supplying SF₆ gas as a fluorine-containing gas, a gas supply unit 26 supplying SiF₄ gas as a fluorine-containing gas (also as a silicon-containing gas), a gas supply unit 27 supplying O₂ gas as an oxygen-containing gas, a gas supply unit 28 supplying Ar gas as an inert gas, and a supply pipe 29 which is at one end connected to an upper surface of the upper chamber 13 and at the other end branched and connected to the gas supply units 25, 26, 27, and 28. The SF₆ gas, SiF₄ gas, O₂ gas, and Ar gas supplied from the gas supply units 25, 26, 27, and 28 are supplied as the processing gas into the processing chamber 11 through the supply pipe 29.

The plasma generating device 30 generates the so-called inductively coupled plasma (ICP). The plasma generating device 30 consists of a spiral (annular) coil 31 disposed on the upper chamber 13 and an RF power supply (coil power supply unit) 32 supplying RF power to the coil 31. By RF power being supplied to the coil 31 by the RF power supply 32, plasma is generated from the processing gas supplied in the upper chamber 13.

The RF power supply 35 supplies RF power to the platen 15 to produce a potential difference (bias potential) between the platen 15 and plasma, thereby making ions generated by the generation of plasma from the processing gas incident to the wafer W. Thereby, the wafer W is etched. Etching herein means dry etching such as RIE (Reactive Ion Etching) using a reaction gas.

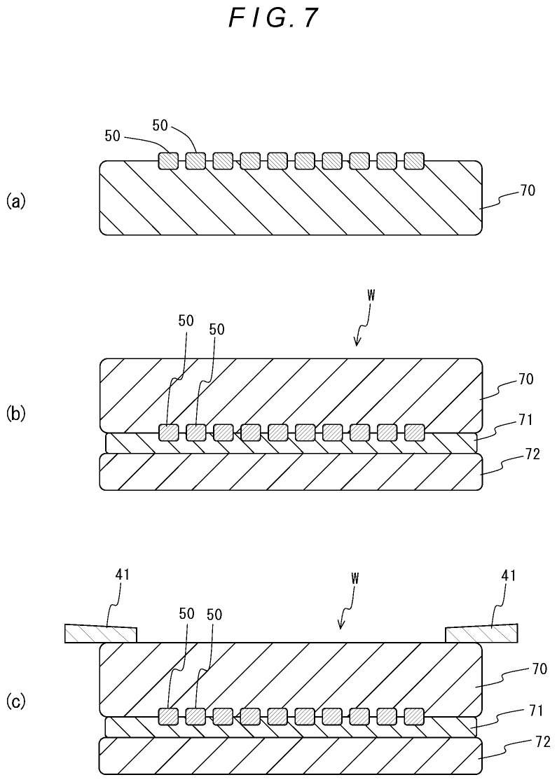

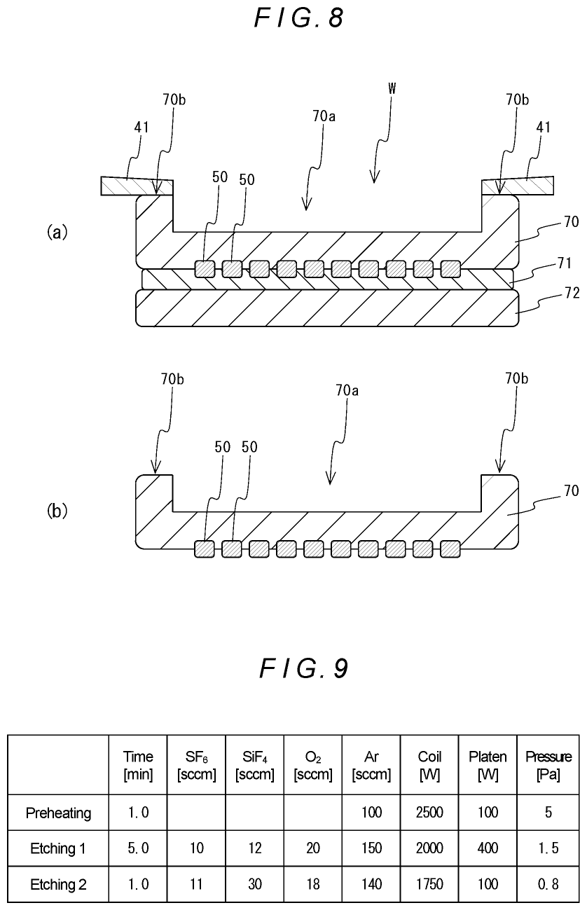

FIGS. 7 and 8 are illustrative diagrams showing steps for manufacturing the semiconductor substrate 70 illustrated in FIG. 1. A method of manufacturing the semiconductor substrate 70 is now described below with reference to FIGS. 7 and 8.

First, a wafer W is manufactured in accordance with the following steps. That is to say, as shown in FIG. 7(a), a semiconductor substrate 70 having devices 50 formed on one surface thereof is prepared. This semiconductor substrate 70 has a typical circular-plate shape (having a thickness of 0.35 mm with respect to a diameter of 76 mm to 150 mm) and is made of silicon carbide.

Subsequently, an adhesive 71 is applied on the entire surface having the devices 50 formed thereon with an applier (not illustrated). For example, a spin coating method is used in which the semiconductor substrate 70 is rotated at high speed so that the adhesive 71, which is dropped, is spread over the entire surface having the devices 50 formed thereon by centrifugal force. Therefore, it is preferred that the adhesive 71 has an appropriate viscosity and is dropped in a liquid state onto the semiconductor substrate 70. For example, a polyimide adhesive or an acrylic adhesive is used as the adhesive 71. Subsequently, a carrier substrate 72 is affixed to the semiconductor substrate 70 via the adhesive 71 (see FIG. 7(b)). Affixing the carrier substrate 72 in this manner enables the devices 50 to be protected by the carrier substrate 72 and makes it easy to remove the carrier substrate 72 after the semiconductor substrate 70 is etched. Note that the devices 50 may be protected, for example, by a protective coating material alone without affixing the carrier substrate 72. In such a case, it is unnecessary to affix the carrier substrate 72.

Thereafter, the thus-manufactured wafer W is loaded into the processing chamber 11 of the etching apparatus 1 and placed onto the platen 15 (the upper member 16) such that the surface not having the devices 50 formed thereon of the semiconductor substrate 70 faces upward as an upper surface. When this process is carried out, the platen 15 has been lowered and the cover member 41 is supported by the support member 42. Subsequently, the wafer W is lifted together with the platen 15, and simultaneously the cover member 41 is raised in a state of being placed on an outer peripheral edge of the wafer W. Thereby, a peripheral portion of a width of about 3 mm of the upper surface of the wafer W is masked by the cover member 41 (see FIG. 7 (c)).

By etching the wafer W by RIE (Reactive Ion Etching) in this state, as shown in FIG. 8(a), only the area inside the peripheral portion of the upper surface of the semiconductor substrate 70, i.e., the first substrate region 70a, is etched with only the peripheral portion of the upper surface of the semiconductor substrate 70, i.e., the second substrate region 70b, remaining unetched. Thereby, a recess is formed. That is to say, the first substrate region 70a of the semiconductor substrate 70 is thinned. Note that it is preferred that the inner diameter of the cover member 41 is determined such that a peripheral portion of a radial width of 1 mm to 10 mm of the upper surface of the semiconductor substrate 70 is covered by the cover member 41, in other words, such that the second substrate region 70b of the semiconductor substrate 70 has a radial width of 1 mm to 10 mm. This is because the second substrate region 70b as having a width smaller than 1 mm makes the semiconductor substrate 70 insufficient in strength, while the second substrate region 70b as having a width greater than 10 mm makes an effective area for formation of the devices 50 smaller. Particularly, the effective area greatly depends on the shape and size of each device 50, arrangement of the devices 50, and the shape of the first substrate region 70a where the devices 50 are formed. In the case where the first substrate region 70a has a circular planar shape, it is preferred that the second substrate region 70b has a width of 5 mm or less. In the case where the first substrate region 70a has a polygonal planar shape, in some cases, the semiconductor substrate 70 has a sufficient effective area for formation of the devices 50 even when the second substrate region 70b has a width of 5 mm or more.

An example of the above-described etching process is shown in FIG. 9. The etching process shown in FIG. 9 consists of three steps, namely, Preheating, Etching 1, and Etching 2.

In the Preheating step, Ar gas is supplied from the gas supply unit 28 into the upper chamber 13 at a flow rate of 100 sccm in the state where the pressure inside the processing chamber 11 is set at 5 Pa, RF power of 100 W is supplied to the platen 15, and RF power of 2500 W is supplied to the coil 31. In this Preheating step, Ar ions are generated by generation of plasma from the Ar gas supplied into the upper chamber 13, and the generated ions are made incident to the semiconductor substrate 70 by a bias potential. Thereby, the semiconductor substrate 70 is heated. In this example, the Preheating step is performed for 1 minute to heat the semiconductor substrate 70 to approximately 200° C. or more.

In the Etching 1 step that follows the Preheating step, SF₆ gas, SiF₄ gas, O₂ gas, and Ar gas are supplied from the gas supply units 25, 26, 27, and 28 into the upper chamber 13 at flow rates of 10 sccm, 12 sccm, 20 sccm, and 150 sccm, respectively, in the state where the pressure inside the processing chamber 11 is set at 1.5 Pa, RF power of 400 W is supplied to the platen 15, and RF power of 2000 W is supplied to the coil 31. The semiconductor substrate 70 is etched for 5 minutes under these conditions, whereby a recess that corresponds to the first substrate region 70a is formed.

In this Etching 1 step, etching of the semiconductor substrate 70 by reaction of an etching species and sputtering by ions generated by generation of plasma from the gases proceeds in parallel with formation of a passivation film on the etched surface by a passivation-film forming species produced by the generation of plasma from the gases and sputtering. Therefore, etching on the side surface of the recess is suppressed by the passivation film formed, while etching on the bottom surface of the recess proceeds by the ion sputtering and the reaction of the etching species. Thus, the so-called anisotropic etching is realized, so that etching in the depth direction proceeds. Specifically, the generation of plasma from the SF₆ gas and SiF₄ gas generates fluorine ions and an etching species (e.g., fluorine radicals), which etch the semiconductor substrate 70. The generation of plasma from the O₂ gas generates oxygen ions and a passivation-film forming species (0). The generated oxygen ions etch the semiconductor substrate 70 by sputtering. On the other hand, the generated passivation-film forming species (0) reacts with a passivation-film forming species (Si) generated by the ion sputtering and a passivation-film forming species (Si) generated from the SiF₄ gas, whereby a passivation film of SiO₂ is formed on the etched surface.

Because the etching proceeds in parallel with the passivation-film formation as described above, the etching rate at the connecting portion between the first substrate region 70a and the second substrate region 70b formed on the semiconductor substrate 70 is somewhat slower than the etching rate at the region located on the inner side of the connecting portion. Therefore, the connecting portion is formed to include in its vertical cross section shape the arc portion having a predetermined radius of curvature r. In this embodiment, since the semiconductor substrate 70 is heated to 200° C. or more by executing the above-described Preheating step, the etching on the bottom surface of the recess by the reaction of the etching species in this Etching 1 step is facilitated as compared with the case where the Preheating step is not executed. Also in this respect, an arcuate shape is easily formed in the connecting portion.

In the Etching 2 step that follows the Etching 1 step, SF₆ gas, SiF₄ gas, O₂ gas, and Ar gas are supplied from the gas supply units 25, 26, 27, and 28 into the upper chamber 13 at flow rates of 11 sccm, 30 sccm, 18 sccm, and 140 sccm, respectively, in the state where the pressure inside the processing chamber 11 is set at 0.8 Pa, RF power of 100 W is supplied to the platen 15, and RF power of 1750 W is supplied to the coil 31. The semiconductor substrate 70 is etched for 1 minute under these conditions, whereby the recess corresponding to the first substrate region 70a is further etched.

In this Etching 2 step, similarly to the Etching 1 step, etching on the bottom surface of the recess proceeds by reaction of etching species and sputtering of ions generated by generation of plasma from the gases, while etching on the side surface of the recess is suppressed by a passivation film formed; therefore, an arcuate shape is easily formed in the connecting portion. Furthermore, since the supply of the SiF₄ gas that produces the passivation-film forming species (Si) is more than twice of that in the Etching 1 step and the RF power supplied to the platen 15 is ¼ that in the Etching 1 step, a stronger passivation film is formed at the connecting portion and the etching rate at the connecting portion is even slower than the etching rate at the region located on the inner side of the connecting portion, so that an arcuate shape is more clearly formed in the connecting portion.

Note that the etching process and conditions shown in FIG. 9 are just an example, and the etching process and conditions for manufacturing the semiconductor substrate 70 illustrated in FIGS. 1 to 5 are not limited to those shown in FIG. 9. For example, the Preheating step is not an essential step. Further, it is not always necessary to execute two etching steps. The etching process may include either one of the Etching 1 step and Etching 2 step, and the time length of the step can be set appropriately.

Further, the etching process may be configured to execute the Etching 1 step under the conditions that SiF₄ gas is not supplied and the RF power supplied to the platen 15 is in the range of 1000 W to 2000 W and then execute the Etching 2 step. Applying a high bias potential in this manner enables the side surface of the recess to be etched by ion sputtering; therefore, it is possible to form the side surface of the recess into a reverse tapered shape. In such a case, the angle θ formed between the linear portion 70a₁ and the linear portion 70a₃ can be in the range of 80° to 90°.

In summary, the process of manufacturing the semiconductor substrate 70 illustrated in FIGS. 1 to 5 requires at least one etching step, and the following etching conditions can be employed: SF₆ gas as an etching gas is suppled into the processing chamber 11 at a flow rate of 10-500 sccm; O₂ gas is optionally supplied into the processing chamber 11 at a flow rate of 10-600 sccm; and SiF₄ gas is optionally supplied into the processing chamber 11 at a flow rate of 5-30 sccm. The O₂ gas contributes to both the etching and the passivation film formation, and the SiF₄ gas contributes mainly to the passivation film formation.

Further, the RF power supplied to the coil 31 can be set in a range of 400 to 5000 W. In view of the plasma stability, it is particularly preferred that it is 1500 W or more. Further, the RF power supplied to the platen 15 can be set in a range of 50 to 2000 W. In view of the etching rate, it is particularly preferred that it is 100 W or more. The pressure inside the processing chamber 11 can be set in a range of 0.5 to 50 Pa. In view of the in-plane uniformity of etching, it is particularly preferred that it is 3 to 30 Pa.

After the upper surface of the semiconductor substrate 70 is etched in the above-described manner and thereby the recess (first substrate region 70a) having a predetermined depth is formed, the etching process is ended and the wafer W is unloaded from the processing chamber 11.

Differently from the conventional art, this manufacturing method does not employ grinding. Therefore, it is unnecessary to carry out a stress relief process using CMP or the like in order to remove grinding distortion, such as a damaged layer, generated in grinding, which enables reduction of manufacturing time and manufacturing cost. Furthermore, even a small rectangular recess can be easily formed by setting the shape of the cover appropriately.

Note that this embodiment is configured such that the etching apparatus 1 has a mechanism for covering the non-etched portion of the wafer W; however, the present disclosure is not limited thereto. For example, a configuration is possible in which a mechanism for covering the non-etched portion of the wafer W is attached to the wafer W.

Thereafter, as shown in FIG. 8(b), the carrier substrate 72 is peeled off from the adhesive 71 and then the adhesive 71 is removed so that the devices 50 are exposed.

The semiconductor substrate 70 according to this embodiment that is manufactured in the above-described manner has a large thickness at its outer peripheral portion, i.e., the second substrate region 70b, and has a small thickness only at its inner region, i.e., the first substrate region 70a, for forming the devices 50 thereon. Therefore, cracking and warpage of the semiconductor substrate 70 are reduced. Further, since the semiconductor substrate 70, on which the devices 50 are formed, is made of silicon carbide and has a minimum thickness (not less than 10 μm and not more than 50 μm) capable of withstanding high voltage, the devices 50 have lower power loss than a device manufactured with silicon.

Further, with the manufacturing method according to this embodiment for manufacturing the semiconductor substrate 70, the semiconductor substrate 70 made of silicon carbide that has high hardness can be thinned to a minimum thickness (not less than m and not more than 50 μm) having high voltage withstanding property by a plasma etching method without depending on mechanical grinding. Therefore, expensive abrasives for grinding are not needed, which greatly reduces manufacturing cost.

### Second Embodiment

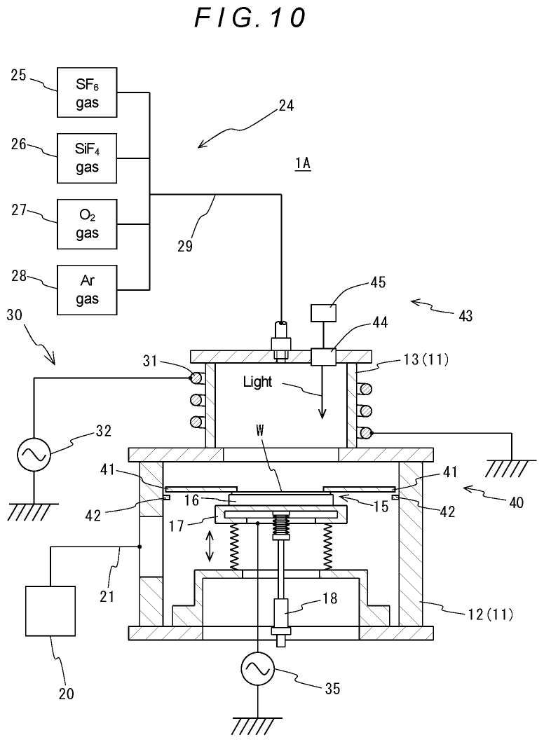

Next, a second embodiment is described based on FIG. 10. FIG. 10 is a sectional view of a schematic configuration of an etching apparatus 1A according to the second embodiment. The etching apparatus 1A is different from the etching apparatus 1 illustrated in FIG. 6 in that the etching apparatus 1A is configured to further include a spectroscopic depth monitor 43 which is capable of measuring (monitoring) the depth of etching of a wafer W in real time. Accordingly, in FIG. 10, components identical to those of the etching apparatus 1 illustrated in FIG. 6 are denoted by the same reference numerals as in FIG. 6 and detailed description thereof is omitted in the description below.

The depth monitor 43 includes a depth sensor 44 and a processing unit 45. The depth sensor 44 includes a multi-wavelength light source (not illustrated) radiating a white light toward the surface to be etched of the wafer W and the cover member 41, a light receiving unit (not illustrated) receiving reflected lights from the wafer W and the cover member 41, and a spectrophotometer (not illustrated). The depth sensor 44 obtains a depth signal which changes in accordance with the depth of etching, and outputs the obtained depth signal to the processing unit 45.

The depth sensor 44 is embedded in the upper surface of the upper chamber 13 and arranged to face the surface of the wafer W and the surface of the cover member 41. During etching of the wafer W, a white light is radiated from the light source toward the wafer W and the cover member 41, and reflected lights from the wafer W and the cover member 41 are received by the light receiving unit. The spectrophotometer measures intensity of light at each wavelength in a predetermined wavelength range for each of the reflected lights and transmits light intensity data obtained to the processing unit 45. The light intensity data is a depth signal in which the depth of etching is reflected and which changes in accordance with the depth of etching. The processing unit 45 generates based on the light intensity data a spectrum representing the intensity of light at each wavelength, and uses the generated spectrum to calculate the depth of etching based on a phase difference between the reflected light reflected by the etched surface of the wafer W and the reflected light reflected by the cover member 41.

Note that the reflected light reflected by the wafer W and the reflected light reflected by the cover member 41 interfere with each other. The manner of interference between their light waves changes in accordance with the depth of the wafer W; therefore, this change of the manner of interference can be used to calculate the depth of etching.

The method of manufacturing the semiconductor substrate 70 with the etching apparatus 1A according to this embodiment provides the same effects as the manufacturing method using the etching apparatus 1 according to the first embodiment. Further, the etching apparatus 1A according to this embodiment is capable of monitoring the etching depth in real time; therefore, the etching apparatus 1A can start etching without carrying out previous steps such as measuring in advance an etching amount and calculating an etching rate so as to recognize an etching end point based on the etching rate and an etching time. Therefore, as compared with the etching apparatus 1 according to the first embodiment, the etching apparatus 1A according to this embodiment greatly reduces the manufacturing time.

Hereinbefore, specific embodiments of the present disclosure have been described. However, the present disclosure is not limited to the embodiments described above and can be implemented differently.

For example, in the above embodiments, silicon carbide having a crystal structure of 4H—SiC is used as the semiconductor substrate 70. However, the material of the semiconductor substrate 70 is not limited to such silicon carbide and may be, for example, silicon carbide having a crystal structure other than 4H—SiC (6H—SiC or 3C—SiC), gallium nitride (GaN), gallium oxide (GaO), or diamond (C). In such cases, the same effects as those in the above embodiments are provided.

Further, in the above embodiments, the semiconductor substrate according to the present disclosure is manufactured by using the etching apparatus 1 or the etching apparatus 1A. However, the manufacturing method according to the present disclosure may be implemented by using an etching apparatus configured differently from them. Further, the above embodiments are configured such that the devices 50 are first formed on the semiconductor substrate 70 and then the first substrate region 70a as the inner region, where the devices 50 are formed, of the semiconductor substrate 70 is thinned by etching. However, the present disclosure is not limited to such a configuration. For example, a configuration is possible in which the first substrate region 70a as the inner region of the semiconductor substrate 70 is first thinned by etching and then the devices 50 are formed in the thinned region (thin-plate part) of the semiconductor substrate 70. In such a case, the devices 50 may be formed on the lower surface (back surface) of the first substrate region 70a as illustrated in FIG. 1 or may be formed on the bottom surface of the recess corresponding to the first substrate region 70a.

Further, instead of the fluorine-containing gas (SF₆ gas) used as the etching gas in the above embodiments, for example, a chlorine-containing gas, such as Cl₂ gas, BCl₃ gas, CCl₄ gas, or SiCl₄ gas, may be used. The manufacturing method using such a gas also provides the same effects as the above manufacturing methods.

Further, the foregoing description of the above embodiments describes an example in which the etching apparatus 1, 1A has a covering mechanism provided thereon which covers only a peripheral edge portion of the semiconductor substrate 70 so that only the peripheral edge portion is not etched. However, the present disclosure is not limited to such a configuration. For example, a configuration is possible in which a case for inserting the wafer W therein is used and the case has a cover provided thereon which covers only a peripheral edge portion of the semiconductor substrate 70 so that only the peripheral edge portion is not etched. Alternatively, a configuration is possible in which an etching mask, such as a photoresist mask, an oxide film mask, or a metal mask, is formed on a peripheral edge portion of the semiconductor substrate 70 so that only the peripheral edge portion is not etched.

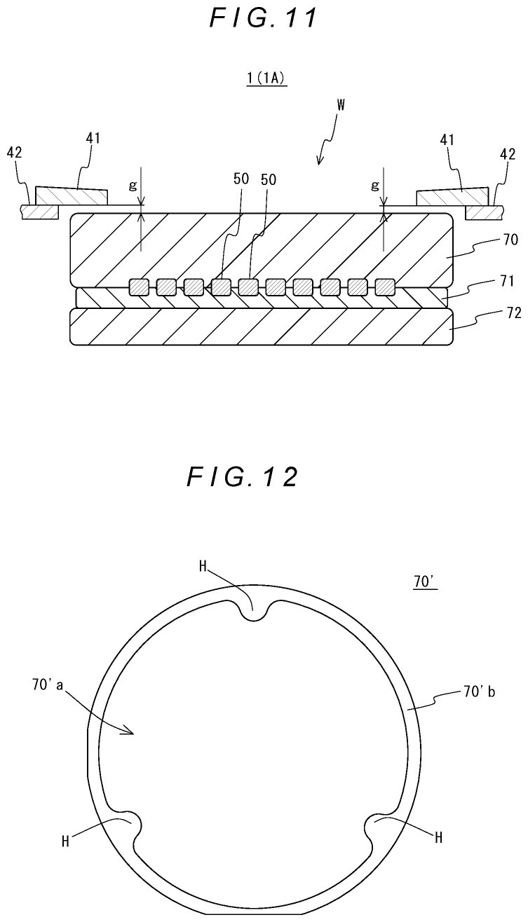

Further, the above embodiments are configured such that etching is performed with the cover member 41 placed on the semiconductor substrate 70. However, the manufacturing apparatus (etching apparatus) and manufacturing method according to the present disclosure are not limited to such a configuration. As shown in FIG. 11, the etching apparatus 1, 1A may be configured such that the cover member 41 is supported by the support member 42 such that a gap g is formed between the upper surface of the semiconductor substrate 70 and the lower surface of the cover member 41 when the platen 15 reaches a lifting end. Further, the manufacturing method may be configured such that etching is performed with the gap g formed between the upper surface of the semiconductor substrate 70 and the lower surface of the cover member 41.

In the case where the cover member 41 is in contact with the semiconductor substrate 70 when the semiconductor substrate 70 is etched in a state where a bias potential is applied to the platen 15, depending on the material of the cover member 41 (for example, in the case of alumina), a bias potential is generated in the cover member 41. This causes a problem that the cover member 41 is sputtered by ions in the plasma and the product of the sputtering adheres to the surface of the first substrate region 70a (the inner surface of the recess) as the inner region of the semiconductor substrate 70, which deteriorates surface accuracy of the surface of the first substrate region 70a. Accordingly, a gap g is formed between the semiconductor substrate 70 and the cover member 41 so that a bias potential is not generated in the cover member 41. Thereby, the surface accuracy of the surface of the first substrate region 70a (the inner surface of the recess) is prevented from being deteriorated due to the cover member 41 being sputtered.

Note that it is preferred that the gap g between the semiconductor substrate 70 and the cover member 41 is not less than 0.5 mm and not more than 3 mm. In the case where the gap g is smaller than 0.5 mm, generation of a bias potential in the cover member 41 is not effectively prevented. In the case where the gap g is equal to or greater than 3 mm, an etching species enters between the semiconductor substrate 70 and the cover member 41 and etches the region covered by the cover member 41 (the second substrate region) of the semiconductor substrate 70, which causes a problem that the shape of the semiconductor substrate 70 obtained is deteriorated, e.g., an inner peripheral edge (inner shoulder) of the second substrate region (thick-plate part) being etched.

Further, the semiconductor substrate 70 may have one or more protrusions which protrude in the radially inward direction from the second substrate region (thick-plate part). A semiconductor substrate having such protrusions is illustrated in FIG. 12. The semiconductor substrate 70′ illustrated in FIG. 12 has three protrusions H, and the three protrusions H are arranged at equal intervals in the circumferential direction of the second substrate region 70′b. For example, if the thin-plate part 70′a is supported by support pins when the semiconductor substrate 70′ is supported at the recess 70′c side in the above-described steps of peeling off the carrier substrate 72 and removing the adhesive 71, the support pins can pierce the supported portions of the thin-plate part 70′a because the thin-plate part 70′a has very small thickness. Accordingly, inwardly protruding protrusions H are formed on the thick-plate part (second substrate region) 70′b so that the protrusions H that has large thickness are supported by the support pins. This configuration can increase the area of the thin-plate part 70′a as much as possible so that the number of devices is increased, and simultaneously can prevent the disadvantage that the semiconductor substrate 70′ is pierced by the support pins. Note that the number of protrusions H provided is not particularly limited. However, in view of stably supporting the semiconductor substrate 70′, it is preferred that three or more protrusions H are formed and the protrusions H are arranged at equal intervals in the circumferential direction of the second substrate region 70′b.

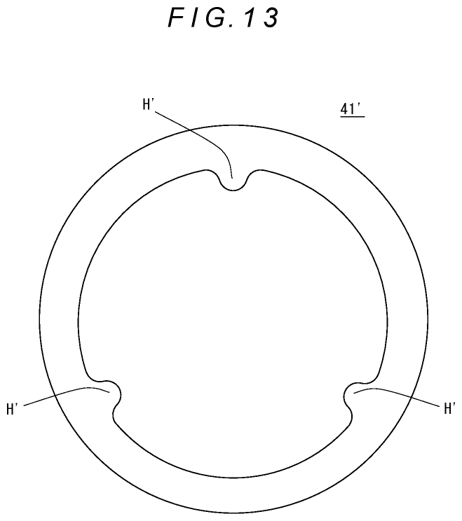

Furthermore, in order to form such protrusions H, the cover member 41 of the above-described etching apparatus 1, 1A also needs to have one or more, preferably three or more, protrusions protruding in the radially inward direction. In the case where two or more protrusions are provided, it is preferred that the protrusions are arranged at equal intervals in the circumferential direction. For the sake of clarity, a cover member having such protrusions is illustrated in FIG. 13. In FIG. 13, reference numeral 41′ denotes the cover member and reference numeral H′ denotes the protrusions.

As have been mentioned, the above-described embodiments are given by way of example only, and various modifications are possible without departing from the scope of the present disclosure. All references, including publications, patent applications, and patents, cited herein are hereby incorporated by reference. All methods described herein can be performed in any suitable order unless otherwise indicated herein or otherwise clearly contradicted by context. The use of any and all examples, or exemplary language (e.g., “such as”) provided herein, is intended to illuminate the disclosed subject matter and does not pose a limitation on the scope of the claims. Any statement herein as to the nature or benefits of the exemplary embodiments is not intended to be limiting, and the appended claims should not be deemed to be limited by such statements. More generally, no language in the specification should be construed as indicating any non-claimed element as being essential to the practice of the claimed subject matter. The scope of the claims includes all modifications and equivalents of the subject matter recited therein as permitted by applicable law. Moreover, any combination of the above-described elements in all possible variations thereof is encompassed by the claims unless otherwise indicated herein or otherwise clearly contradicted by context. Additionally, aspects of the different embodiments can be combined with or substituted for one another. Finally, the description herein of any reference or patent, even if identified as “prior,” is not intended to constitute a concession that such reference or patent is available as prior art against the present disclosure.

What is claimed is:

1. A wide-gap semiconductor substrate for forming a device thereon, comprising:
a first substrate region as an inner region having a recessed shape; and
a second substrate region as an annular region formed to surround an outer periphery of the first substrate region, wherein:
a connecting portion as a peripheral edge of the recessed shape of the first substrate region connecting to the second substrate region includes in its vertical cross section shape an arc portion having a predetermined radius of curvature; and
the device is formed on the first substrate region.

2. The wide-gap semiconductor substrate of claim 1, wherein the radius of curvature of the arc portion included in the connecting portion is not less than 0.1 μm and not more than 1000 μm.

3. The wide-gap semiconductor substrate of claim 1, wherein the radius of curvature of the arc portion included in the connecting portion is not less than 1 μm and not more than 100 μm.

4. The wide-gap semiconductor substrate of claim 1, wherein the first substrate region is formed by dry etching.

5. The wide-gap semiconductor substrate of claim 1, wherein:
a first thickness as a thickness of a region located on an inner side of the connecting portion of the first substrate region is not less than 10 μm and not more than 50 μm;
a second thickness as a thickness of the second substrate region is not less than 100 μm and not more than 350 μm; and
a radial width of the second substrate region is not less than 1 mm and not more than 10 mm.

6. A wide-gap semiconductor substrate manufacturing apparatus configured to thin a device formation region of a wide-gap semiconductor substrate placed on a platen disposed in a processing chamber by etching using plasma generated from an etching gas to form a first substrate region as an inner region having a recessed shape and a second substrate region as an annular region surrounding an outer periphery of the first substrate region, the wide-gap semiconductor substrate manufacturing apparatus being able to perform the etching such that a connecting portion as a peripheral edge of the recessed shape of the first substrate region connecting to the second substrate region includes in its vertical cross section shape an arc portion having a predetermined radius of curvature, comprising:
an outer-periphery covering mechanism including a cover member covering, during the etching, the second substrate region of the wide-gap semiconductor substrate placed on the platen to cause the device formation region not covered by the cover member to be etched and thinned.

7. The wide-gap semiconductor substrate manufacturing apparatus of claim 6, wherein:
the outer-periphery covering mechanism further includes a support member provided in the processing chamber and supporting the cover member; and
the support member supports the cover member such that the cover member covers the second substrate region of the wide-gap semiconductor substrate with a gap formed between the cover member and the wide-gap semiconductor substrate.

8. The wide-gap semiconductor substrate manufacturing apparatus of claim 7, wherein the support member supports the cover member such that a gap of not less than 0.5 mm and not more than 3 mm is formed between the cover member and the wide-gap semiconductor substrate.

9. The wide-gap semiconductor substrate manufacturing apparatus of claim 6, wherein:
the outer-periphery covering mechanism further includes a support member provided in the processing chamber and supporting the cover member; and
the outer-periphery covering mechanism is configured such that the cover member is brought into contact with and raised by the second substrate region of the wide-gap semiconductor substrate when the wide-gap semiconductor substrate is lifted by the platen, thereby covering the second substrate region of the wide-gap semiconductor substrate placed on the platen so that the second substrate region is not etched.

10. The wide-gap semiconductor substrate manufacturing apparatus of claim 6, wherein the cover member is made of quartz, aluminum oxide, or yttria or made of a material made by coating quartz, aluminum oxide, or yttria with a metal coating.

11. The wide-gap semiconductor substrate manufacturing apparatus of claim 6, wherein:
the wide-gap semiconductor substrate manufacturing apparatus further comprises a depth monitor detecting a depth of etching of the wide-gap semiconductor substrate; and
the depth monitor includes:
a depth sensor including a light source radiating a light toward an etched surface of the wide-gap semiconductor substrate and the cover member; and
a processing unit calculating the depth of etching based on reflected lights reflected by the etched surface and the cover member.

12. A wide-gap semiconductor substrate manufacturing method configured to thin a device formation region of a wide-gap semiconductor substrate placed on a platen disposed in a processing chamber by etching using plasma generated from an etching gas to form a first substrate region as an inner region having a recessed shape and a second substrate region as an annular region surrounding an outer periphery of the first substrate region, the wide-gap semiconductor substrate manufacturing method being able to perform the etching such that a connecting portion as a peripheral edge of the recessed shape of the first substrate region connecting to the second substrate region includes in its vertical cross section shape an arc portion having a predetermined radius of curvature, comprising:
placing the wide-gap semiconductor substrate onto the platen disposed in the processing chamber and covering the second substrate region of the wide-gap semiconductor substrate with a cover member;
supplying the etching gas into the processing chamber and generating the plasma from the etching gas; and
applying a bias potential to the platen to etch and thin the device formation region corresponding to the first substrate region of the wide-gap semiconductor substrate.

13. The wide-gap semiconductor substrate manufacturing method of claim 12, wherein a gap is formed between the wide-gap semiconductor substrate and the cover member.

14. The wide-gap semiconductor substrate manufacturing method of claim 13, wherein a gap of not less than 0.5 mm and not more than 3 mm is formed between the wide-gap semiconductor substrate and the cover member.

15. The wide-gap semiconductor substrate manufacturing method of claim 12, wherein the cover member is made of quartz, aluminum oxide, or yttria or made of a material made by coating quartz, aluminum oxide, or yttria with a metal coating.

16. The wide-gap semiconductor substrate manufacturing method of claim 12, wherein the etching is performed such that a region located on an inner side of the connecting portion of the first substrate region has a thickness of not less than 10 μm and not more than 50 μm.

17. The wide-gap semiconductor substrate manufacturing method of claim 12, wherein, before the etching gas is supplied into the processing chamber for the etching, the wide-gap semiconductor substrate is preheated by supplying an inert gas into the processing chamber and generating plasma from the inert gas and applying a bias potential to the platen.

18. The wide-gap semiconductor substrate manufacturing method of claim 17, wherein the wide-gap semiconductor substrate is preheated to 200° C. or more.

19. The wide-gap semiconductor substrate manufacturing method of claim 12, wherein the etching gas includes a fluorine-containing gas.

20. The wide-gap semiconductor substrate manufacturing method of claim 12, wherein:
the bias potential is applied to the platen by supplying an RF power of 50 W or more to the platen; and
a pressure inside the processing chamber is 30 Pa or less.
